(19) United States
(12) Patent Application Publication
(10) Pub. No.: US 2017/0365555 A1
(43) Pub. Date: Dec. 21, 2017

(54) Semiconductor Devices and Methods of Manufacturing the Same

(71) Applicant: Samsung Electronics Co., Ltd., Suwon-si (KR)

(72) Inventors: Jung-Hun Choi, Seoul (KR); Jeong-Ik Kim, Suwon-si (KR); Chul-Sung Kim, Seongnam-si (KR); Jae-Eun Lee, Ansan-si (KR); Sang-Jin Hyun, Suwon-si (KR)

(21) Appl. No.: 15/389,856

(22) Filed: Dec. 23, 2016

(30) Foreign Application Priority Data
Jun. 15, 2016 (KR) 10-2016-0074765

(51) Int. Cl. H01L 23/535; H01L 23/532; H01L 23/528; H01L 29/78; H01L 29/06

(52) U.S. Cl. CPC H01L 23/535; H01L 29/785; H01L 29/0649; H01L 23/528; H01L 23/53209; H01L 23/53266

(57) ABSTRACT

Semiconductor devices may include a structure on a substrate, an insulating interlayer, a metal silicide pattern, a first barrier pattern, a second barrier pattern and a metal pattern. The structure may include silicon. The insulating interlayer may include a contact hole exposing a surface of the structure. The metal silicide pattern may be in a lower portion of the contact hole, and the metal silicide pattern may directly contact the exposed surface of the structure. The first barrier pattern may directly contact an upper surface of the metal silicide pattern and a sidewall of the contact hole. The first barrier pattern may include a metal nitride. The second barrier pattern may be formed on the first barrier pattern. The second barrier pattern may include a metal nitride. The metal pattern may be formed on the second barrier pattern. The metal pattern may be in the contact hole.

### CROSS-REFERENCE TO RELATED APPLICATION

This application claims priority under 35 USC §119 to Korean Patent Application No. 10-2016-0074765, filed on Jun. 15, 2016, in the Korean Intellectual Property Office (KIPO), the contents of which are herein incorporated by reference in their entirety.

### BACKGROUND

### 1. Field

Example embodiments of the inventive concepts relate to semiconductor devices and methods of manufacturing the same. More particularly, example embodiments of the inventive concepts relate to semiconductor devices including a contact plug and a method of manufacturing the same.

### 2. Description of the Related Art

A semiconductor device may include a transistor. A plurality of contact plugs may be formed to be electrically connected to source/drain regions, respectively, in the transistor.

### SUMMARY

Example embodiments of the inventive concepts may provide semiconductor devices including a contact plug.

According to example embodiments, there is provided a semiconductor device. The semiconductor device includes a structure on a substrate, an insulating interlayer, a metal silicide pattern, a first barrier pattern, a second barrier pattern and a metal pattern. The insulating interlayer may include a contact hole exposing a surface of the structure. The metal silicide pattern may be within a lower portion of the contact hole, and the metal silicide pattern may directly contact the exposed surface of the structure. The first barrier pattern may directly contact an upper surface of the metal silicide pattern and a sidewall of the contact hole. The first barrier pattern may include a metal nitride. The second barrier pattern may be formed on the first barrier pattern. The second barrier pattern may include a metal nitride. The metal pattern may be formed on the second barrier pattern. The metal pattern may be within the contact hole.

According to example embodiments, there is provided a semiconductor device. The semiconductor device includes a substrate including an active fin, a gate structure, an epitaxial structure, an insulating interlayer, a metal silicide pattern, a first barrier pattern, a second barrier pattern and a metal pattern. The active fin may include a plurality of protruding portions and a plurality of recesses between neighboring ones of the protruding portions. The gate structure may extend in a second direction crossing the first direction, and the gate structure may be on one of the protruding portions of the active fin. The epitaxial structure may be within a recess of the plurality of recesses, and may include silicon. The insulating interlayer may be on the epitaxial structure. The insulating interlayer may include a contact hole exposing a surface of the epitaxial structure. The metal silicide pattern may be within a lower portion of the contact hole. The metal silicide pattern may directly contact the exposed surface of the structure. The first barrier pattern may directly contact an upper surface of the metal silicide pattern and a sidewall of the contact hole. The first barrier pattern may include a metal nitride. The second barrier pattern may be on the first barrier pattern. The second barrier pattern may include a metal nitride. The metal pattern may be on the second barrier pattern. The metal pattern may be in the contact hole.

According to example embodiments, there is provided a semiconductor device. The semiconductor device may include a substrate, an insulating interlayer on the substrate an epitaxial structure between the substrate and the insulating interlayer, a contact hole in the insulating interlayer, a bottom portion of the contact hole above the epitaxial structure, a metal silicide pattern in the bottom portion of the contact hole and above the epitaxial structure, and a barrier pattern structure directly on the metal silicide pattern. The barrier pattern structure may include a first barrier pattern directly contacting the metal silicide pattern, and a second barrier pattern on the first barrier pattern. The first barrier pattern may include a metal nitride or a metal oxynitride.

According to example embodiments, the contact plug may include the first barrier pattern including the metal nitride and directly contacting on the metal silicide pattern. That is, a metal interface layer may not be formed between the first barrier pattern and the metal silicide pattern. Thus, failures due to the metal interface layer may decrease. Also, the second barrier pattern may be formed on the first barrier pattern. Thus, a diffusion of a metal in the contact plug may decreased by the first and second barrier patterns.

### BRIEF DESCRIPTION OF THE DRAWINGS

Example embodiments will be more clearly understood from the following detailed description taken in conjunction with the accompanying drawings. FIGS. 1 to 23 represent non-limiting, example embodiments as described herein.

FIGS. 1 and 2 are a cross-sectional view and a plan view, respectively, illustrating a semiconductor device in accordance with example embodiments of the inventive concepts;

FIG. 3 is an enlarged cross-sectional view illustrating a contact plug of the semiconductor device of FIGS. 1 and 2 in accordance with example embodiments of the inventive concepts;

FIG. 4 is a schematic view illustrating a grain boundary of the barrier structure in the contact plug;

FIG. 5 is an enlarged cross-sectional view illustrating a contact plug of a semiconductor device in accordance with example embodiments of the inventive concepts;

FIG. 6 is an enlarged cross-sectional view illustrating a contact plug of a semiconductor device in accordance with example embodiments of the inventive concepts;

FIGS. 7 to 19 are cross-sectional views illustrating stages of a method of manufacturing semiconductor devices in accordance with example embodiments of the inventive concepts;

FIGS. 20 to 23 are cross-sectional views illustrating stages of a method of manufacturing semiconductor devices in accordance with example embodiments of the inventive concepts.

### DETAILED DESCRIPTION

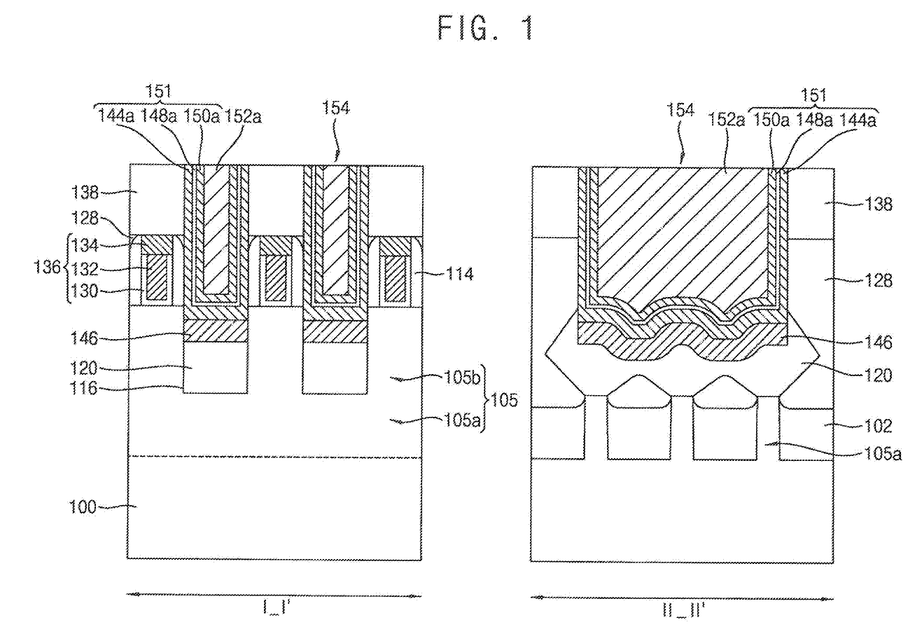

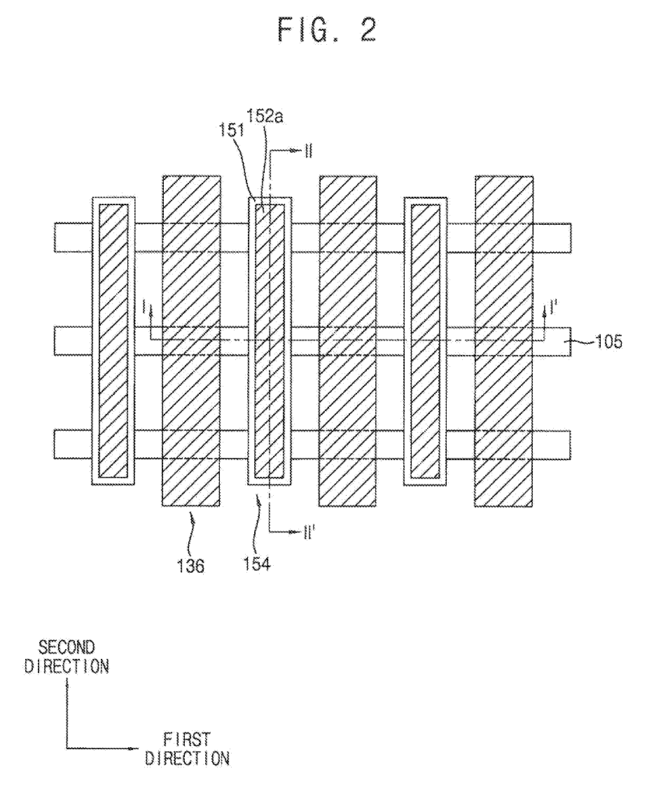

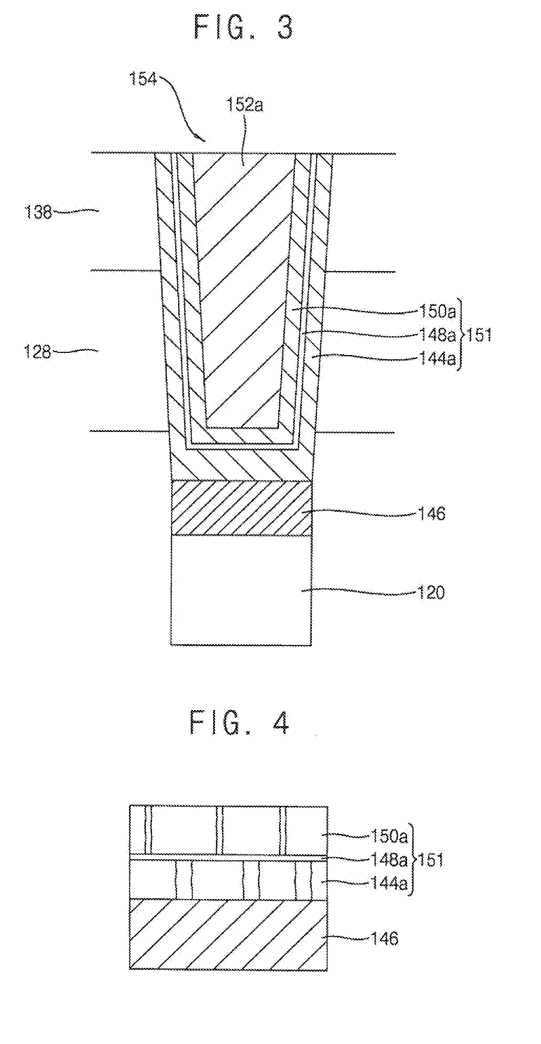

FIGS. 1 and 2 are a cross-sectional view and a plan view, respectively, illustrating a semiconductor device in accordance with example embodiments of the inventive concepts. FIG. 3 is an enlarged cross-sectional view illustrating a contact plug of the semiconductor device of FIGS. 1 and 2 in accordance with example embodiments of the inventive concepts. FIG. 4 is a schematic view illustrating a grain boundary of a barrier structure of the contact plug.

FIG. 1 includes cross-sectional views taken along lines I-I′ and respectively, of the plan view of FIG. 2. In FIGS. 2 and 3, some elements are omitted for the convenience of explanation. For example, a spacer and an insulating interlayer are omitted in FIG. 2, and a gate structure is omitted in FIG. 3.

Referring to FIGS. 1, 2, 3 and 4, the semiconductor device may include a substrate 100 including an active fin 105, a gate structure 136, an epitaxial structure 120 and a contact structure 154. The semiconductor device may further include an isolation layer 102 and spacers 114.

The substrate 100 may include a semiconductor material, e.g., silicon. In some embodiments, the substrate 100 may be a silicon-on-insulator (SOI) substrate, a germanium-on-insulator (GOI) substrate, etc. The substrate 100 may have crystallinity, such as, single crystallinity.

The active fin 105 may include a first pattern 105a extending in a first direction and a second pattern 105b protruding upwardly from a top surface of the first pattern 105a. The active fin 105 may include a material substantially the same as that of the substrate 100. In example embodiments, a plurality of active fins 105 may be arranged in a second direction substantially perpendicular to the first direction. A recess 116 may be formed between the second patterns 105b in the first direction.

The isolation layer 102 may include an oxide, e.g., silicon oxide.

The gate structure 136 may extend in the second direction, and cover a surface of the active fin 105, and a plurality of gate structures 136 may be arranged in the first direction.

In example embodiments, the gate structure 136 may include a gate insulation pattern 130, a gate electrode 132, and a hard mask 134 sequentially stacked on the active fin 105 and the isolation layer 102.

The gate insulation pattern 130 may include an oxide, e.g., silicon oxide, and/or a metal oxide having a high dielectric constant, e.g., hafnium oxide, tantalum oxide, zirconium oxide, etc. In example embodiments, the gate insulation pattern 130 may include a silicon oxide layer and a metal oxide layer sequentially stacked. The gate insulation pattern 130 may be formed on a sidewall and a bottom of the gate electrode 132.

The gate electrode 132 may include a material having a low resistance, e.g., a metal such as aluminum, copper, tantalum, etc., or a metal nitride thereof. In some embodiments, the gate electrode 132 may include, e.g., polysilicon. The hard mask 134 may include a nitride, e.g., silicon nitride.

The spacers 114 may be formed on sidewalls of the gate structure 136, and may include, for example, a nitride, e.g., silicon nitride, silicon oxycarbonitride (SiOCN), etc.

An epitaxial pattern may be formed in the recess 116 between the second patterns 105b. In example embodiments, the epitaxial pattern may have a cross-section taken along the second direction of which a shape may be, for example, a pentagon, hexagon, or rhombus, however the inventive concepts are not limited thereto. A plurality of epitaxial patterns may protrude in the second direction from a portion of the active fin 105 under the recess 116. In example embodiments, neighboring ones of the epitaxial patterns disposed in the second direction may be connected to each other to be merged into a single pattern, which may be referred to as the epitaxial structure 120. Thus, the epitaxial structure 120 may be formed in the recess 116.

The epitaxial structure 120 may serve as source/drain regions of a FinFET, and may be doped with impurities.

In example embodiments, the epitaxial structure 120 may include silicon or silicon germanium. When the FinFET is a negative-channel metal oxide semiconductor (NMOS) transistor, the epitaxial structure 120 may include silicon doped with n-type impurities. When the FinFET has a positive-channel metal oxide semiconductor (PMOS) transistor, the epitaxial structure 120 may include silicon germanium doped with p-type impurities.

In example embodiments, a first insulating interlayer 128 may fill a gap between the gate structures 136, and a second insulating interlayer 138 may be formed on the first insulating interlayer 128. The first and second insulating interlayers 128 and 138 may include substantially the same material, e.g., silicon oxide. At least one of the first and second insulating interlayers 128 and 138 may cover the gate structures 136 and the epitaxial structure 120.

The contact structure 154 may be formed through the first and second insulating interlayers 128 and 138, and may contact an upper surface of the epitaxial structure 120.

The contact structure 154 may include a metal silicide pattern 146, a first barrier pattern 144a, a metal oxynitride pattern 148a, a second barrier pattern 150a and a metal pattern 152a sequentially stacked.

The contact structure 154 may be within and, in some embodiments, substantially fill, a contact hole through the first and second insulating interlayers 128 and 138 that may expose the upper surface of the epitaxial structure 120.

The metal silicide pattern 146 may directly contact the upper surface of the epitaxial structure 120, and may serve as an ohmic pattern. In example embodiments, the metal silicide pattern 146 may be formed along a profile of an upper surface of the epitaxial structure 120. In example embodiments, the metal silicide pattern 146 may be formed only on the upper surface of the epitaxial structure 120 exposed by the contact hole. The metal silicide pattern 146 may include, e.g., titanium silicide, tantalum silicide, etc.

In example embodiments, an upper surface of the metal silicide pattern 146 may be lower than a top surface of the second pattern 105b of the active fin 105.

The first and second barrier patterns 144a and 150a may include a metal nitride. The metal oxynitride pattern 148a may be formed by an oxidation process on the surface of the first barrier pattern 144a.

The first barrier pattern 144a, the metal oxynitride pattern 148a and the second barrier pattern 150a sequentially stacked may be referred to as a barrier pattern structure 151. In example embodiments, the barrier pattern structure 151 may be conformally formed on a sidewall of the contact hole and the upper surface of the metal silicide pattern 146. The first barrier pattern 144a may directly contact the metal silicide pattern 146.

That is, a metal interface layer, e.g., a titanium layer or a tantalum layer may not be formed between the first barrier pattern 144a and the metal silicide pattern 146. The metal interface layer including a metal may be reacted more quickly than the first barrier pattern 144a including a metal nitride. If the metal interface layer is formed between the first barrier pattern 144a and the metal silicide pattern 146, a void may be formed when the metal interface layer is removed, or contamination may be generated due to diffusion of the metal in the metal interface layer or a metal pattern during subsequent processes. However, in example embodiments of the inventive concepts, the first barrier pattern 144a may directly contact the metal silicide pattern 146, so that the formation of the void or the contamination due to the diffusion may be reduced.

The first barrier pattern 144a may include, e.g., titanium nitride, tantalum nitride, etc. In example embodiments, a metal included in the first barrier pattern 144a may be substantially the same as a metal included in the metal silicide pattern 146. In some embodiments, when the metal silicide pattern 146 includes titanium silicide, the first barrier pattern 144a may include titanium nitride. In some embodiments, when the metal silicide pattern 146 includes tantalum silicide, the first barrier pattern 144a may include tantalum nitride.

The second barrier pattern 150a may include, e.g., titanium nitride, tantalum nitride, tungsten nitride, etc. In example embodiments, the second barrier pattern 150a may include a material substantially the same as a material of the first barrier pattern 144a. In some embodiments, the second barrier pattern 150a may include a material different from a material of the first barrier pattern 144a.

In example embodiments, the second barrier pattern 150a may have fewer defects than the first barrier pattern 144a. That is, the number and/or size of the defects included in the second barrier pattern 150a may be less than the number and/or size of the defects included in the first barrier pattern 144a. The first and second barrier patterns 144a and 150a may be formed by deposition processes, respectively, which may be discontinuously performed.

Referring to FIG. 4, grain boundaries may be mismatched at an interface between the first and second barrier patterns 144a and 150a. In example embodiments, a size of the grain boundary of the second barrier pattern 150a may be less than a size of the grain boundary of the first barrier pattern 144a.

The metal oxynitride pattern 148a may be interposed between the first and second barrier patterns 144a and 150a. A metal included in the metal oxynitride pattern 148a may be substantially the same as a metal included in the first barrier pattern 144a. In some embodiments, when the first barrier pattern 144a includes titanium nitride, the metal oxynitride layer 148a may include titanium oxynitride. In some embodiments, when the first barrier pattern 144a includes tantalum nitride, the metal oxynitride layer may include tantalum oxynitride.

The second barrier pattern 150a may have reduced defects, so that the barrier pattern structure 151 may have a good diffusion barrier characteristic.

The first barrier pattern 144a on the sidewall of the contact hole may have a thin thickness so that nitrogen ions may sufficiently permeate into an underlying layer. If the first barrier pattern 144a has a thickness less than about 1 nm, the underlying layer may not be protected by the first barrier pattern 144a. If the first barrier pattern 144a has a thickness greater than about 10 nm, nitrogen ions may not sufficiently permeate into the underlying layer. In example embodiments, the first barrier pattern 144a may have a thickness of about 1 nm to about 10 nm. Preferably, the first barrier pattern 144a may have a thickness of about 1 nm to about 3 nm.

A thickness of the second barrier pattern 150a may be controlled according to the thickness of the first barrier pattern 144a. In example embodiments, the barrier pattern structure 151 may have a thickness of about 2 nm to about 20 nm, and preferably, a thickness of about 2 nm to about 10 nm. A thickness of the second barrier pattern 150a may be determined according to a target thickness of the barrier pattern structure 151.

The metal pattern 152a may be formed on the second barrier pattern 150a, and may be within, and in some embodiments substantially fill, a remaining portion of the contact hole. The metal pattern 152a may include, e.g., tungsten, copper, aluminum, etc.

A conductive pattern (not shown) may be further formed on the contact structure 154. In example embodiments, the conductive pattern may include, e.g., a pad electrode, a conductive line, etc.

As described above, the semiconductor device may include the contact structure 154, which may not include a metal interface layer between the metal silicide pattern 146 and the first barrier pattern 144a including metal nitride. Thus, failures due to the metal interface layer may decrease. Also, the barrier pattern structure 151 may include the first barrier pattern 144a, the metal oxynitride pattern 148a and the second barrier pattern 150a sequentially stacked, so that the barrier pattern structure 151 may have a good diffusion barrier characteristic.

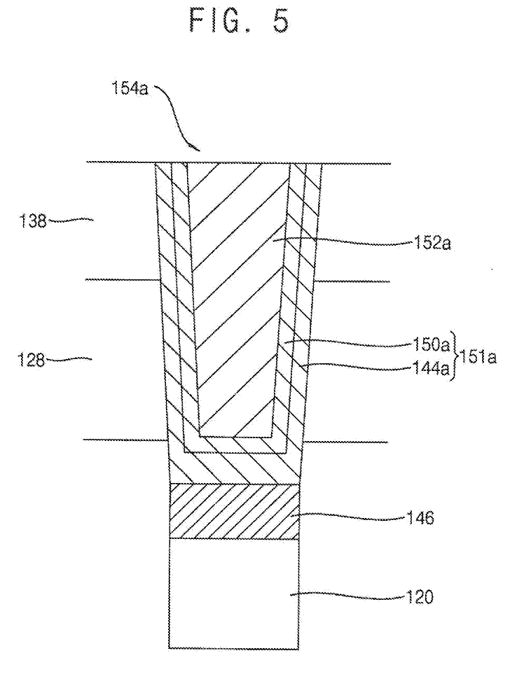

FIG. 5 is an enlarged view illustrating a contact plug of a semiconductor device in accordance with example embodiments of the inventive concepts.

The semiconductor device may be substantially the same as the semiconductor device illustrated with reference to FIGS. 1 to 4, except for the contact structure. Thus, the contact structure will be mainly described herein. In FIG. 5, some elements, e.g., a gate structure are omitted for the convenience of explanation.

Referring to FIG. 5, a contact structure 154a may include the metal silicide pattern 146, the first barrier pattern 144a, the second barrier pattern 150a and the metal pattern 152a sequentially stacked. The contact structure 154a may be formed through the first and second insulating interlayers 128 and 138, and may be within and, in some embodiments, substantially fill, the contact hole exposing the upper surface of the epitaxial structure 120. A profile of a lower surface of the contact hole may be substantially the same as a profile of an upper surface of the epitaxial structure 120.

The metal silicide pattern 146 may directly contact the upper surface of the epitaxial structure 120, and may serve as an ohmic pattern. In example embodiments, the metal silicide pattern 146 may be substantially the same as the metal silicide pattern 146 illustrated with reference to FIGS. 1 to 4.

The first and second barrier patterns 144a and 150a may include a metal nitride. The first and second barrier patterns 144a and 150a sequentially stacked may be referred to as a barrier pattern structure 151a. In example embodiments, the barrier pattern structure 151a may be conformally formed on the sidewall of the contact hole and the upper surface of the metal silicide pattern 146. In some embodiments, the first barrier pattern 144a may directly contact the metal silicide pattern 146.

The first barrier pattern 144a may include, e.g., titanium nitride, tantalum nitride, etc. In example embodiments, a metal included in the first barrier pattern 144a may be substantially the same as a metal included in the metal silicide pattern 146.

The second barrier pattern 150a may include, e.g., titanium nitride, tantalum nitride, tungsten silicide, etc. In example embodiments, the second barrier pattern 150a may include a material substantially the same as a material of the first barrier pattern 144a. In some embodiments, the second barrier pattern 150a may include a material different from a material of the first barrier pattern 144a.

The metal pattern 152a may be formed on the second barrier pattern 150a, and may be within and, in some embodiments, substantially fill a remaining portion of the contact hole. The metal pattern 152a may include, e.g., tungsten, copper, aluminum, etc.

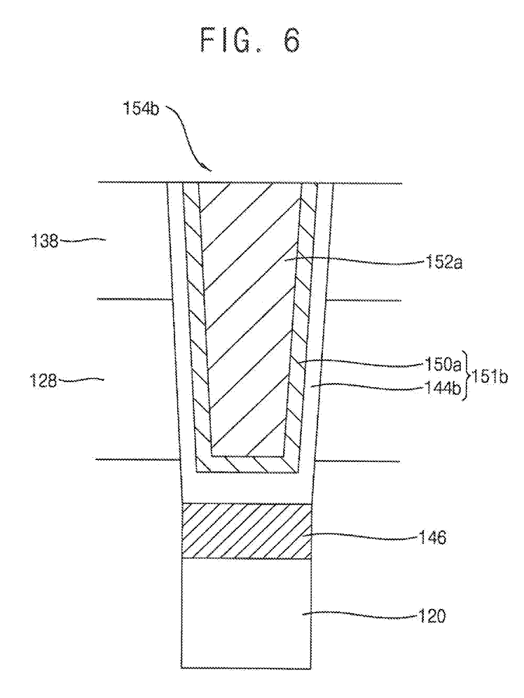

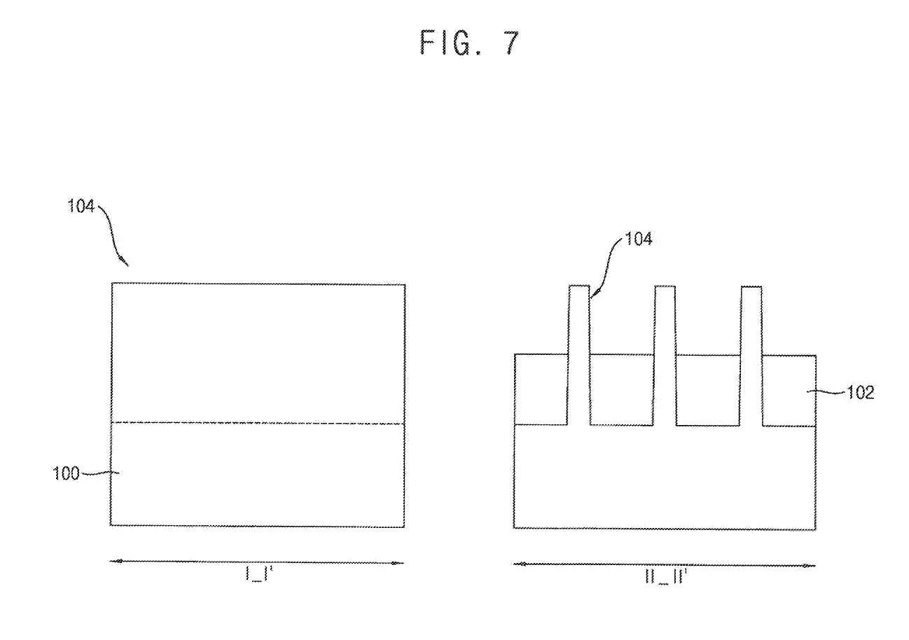

FIG. 6 is an enlarged view illustrating a contact plug of a semiconductor device in accordance with example embodiments of the inventive concepts.

The semiconductor device may be substantially the same as the semiconductor device illustrated with reference to FIGS. 1 to 4, except for the contact structure 154b. Thus, the contact structure 154b will be mainly described. In FIG. 6, some elements, e.g., a gate structure are omitted for the convenience of explanation.

Referring to FIG. 6, a contact structure 154b may include the metal silicide pattern 146, the first barrier pattern 144b, the second barrier pattern 150a and the metal pattern 152a sequentially stacked. The contact structure 154b may be formed through the first and second insulating interlayers 128 and 138, and may be within and, in some embodiments, substantially fill the contact hole exposing the upper surface of the epitaxial structure 120. A profile of a lower surface of the contact hole may be substantially the same as a profile of an upper surface of the epitaxial structure 120.

The metal silicide pattern 146 may directly contact the upper surface of the epitaxial structure 120, and may serve as an ohmic pattern. In example embodiments, the metal silicide pattern 146 may be substantially the same as the metal silicide pattern illustrated with reference to FIGS. 1 to 4.

The first and second barrier patterns 144b and 150a sequentially stacked may be referred to as a barrier pattern structure 151b.

The first barrier pattern 144b may include a metal oxynitride, and the second barrier pattern 150a may include a metal nitride.

In example embodiments, the barrier pattern structure 151b may be conformally formed on the sidewall of the contact hole and the upper surface of the metal silicide pattern 146.

The first barrier pattern 144b may directly contact the metal silicide pattern 146. The first barrier pattern 144b may include, e.g., titanium oxynitride, tantalum oxynitride, etc. In example embodiments, a metal included in the first barrier pattern 144b may be substantially the same as a metal included in the metal silicide pattern 146. In some embodiments, when the metal silicide pattern 146 includes titanium silicide, the first barrier pattern 144b may include titanium oxynitride. In some embodiments, when the metal silicide pattern 146 includes tantalum silicide, the first barrier pattern 144b may include tantalum oxynitride.

The second barrier pattern 150a may include, e.g., titanium nitride, tantalum nitride, tungsten silicide, etc.

In example embodiments, the second barrier pattern 150a may be substantially the same as the second barrier pattern 150a illustrated with reference to FIGS. 1 and 2.

The metal pattern 152a may be formed on the second barrier pattern 150a, and may be within and, in some embodiments, substantially fill a remaining portion of the contact hole. The metal pattern 152a may include, e.g., tungsten, copper, aluminum, etc.

FIGS. 7 to 19 are cross-sectional views illustrating stages of a method of manufacturing the semiconductor device in accordance with example embodiments of the inventive concepts.

Particularly, FIGS. 7 to 19 include cross-sectional views taken along lines I-I′ and II-II′, respectively, in FIG. 2.

Referring to FIG. 7, an upper portion of a substrate 100 may be partially removed to form a trench extending in a first direction, and an isolation layer 102 may be formed on the substrate 100 to fill a lower portion of the trench.

Before forming the trench, impurities may be implanted into the substrate 100 to form a well region (not shown).

In example embodiments, the isolation layer 102 may be formed by forming an insulation layer on the substrate 100 to sufficiently fill the trench, planarizing the insulation layer until a top surface of the substrate 100 may be exposed, and removing an upper portion of the insulation layer to expose an upper portion of the trench. The insulation layer may be formed to include an oxide, e.g., silicon oxide.

Accordingly, as the isolation layer 102 is formed, a plurality of preliminary active fins 104 may be formed on the substrate 100 to extend in the first direction. In example embodiments, the preliminary active fins 104 may be arranged in a second direction substantially perpendicular to the first direction.

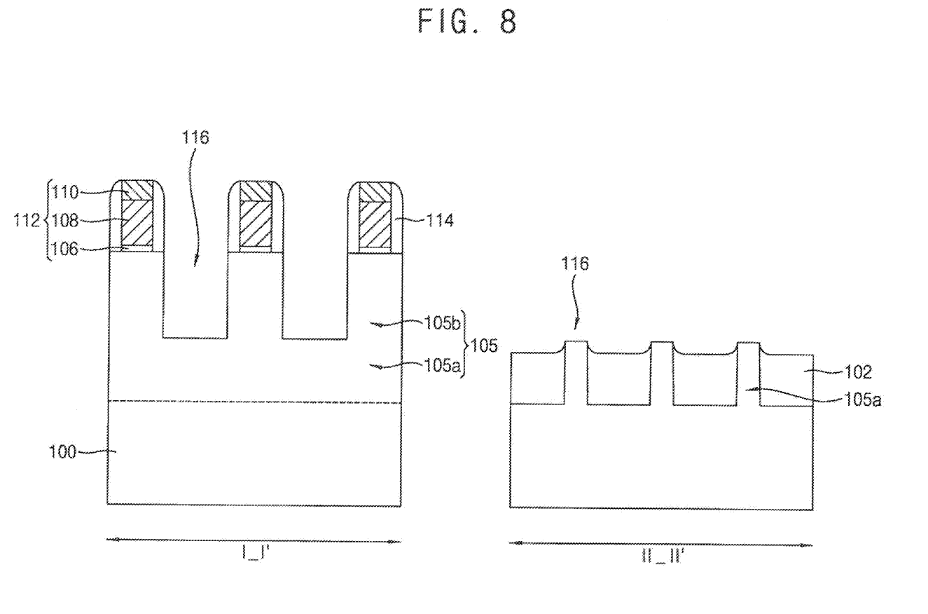

Referring to FIG. 8, a plurality of dummy gate structures 112 may be formed on the substrate 100. Spacers 114 may be formed on sidewalls of each of the dummy gate structure 112. An upper portion of the preliminary active fins 104 may be etched to form a recess 116 between the spacers 114.

Particularly, the dummy gate structures 112 may be formed by sequentially stacking a dummy insulation layer, a dummy gate electrode layer, and a hard mask layer on the preliminary active fins 104 and the isolation layer 102, patterning the hard mask layer by a photolithography process using a photoresist pattern (not shown) to form a hard mask 110, and sequentially etching the dummy gate electrode layer and the dummy insulation layer using the hard mask 110 as an etching mask. Thus, each of the dummy gate structures 112 may be formed to include a dummy insulation pattern 106, a dummy gate electrode 108 and the hard mask 110 sequentially stacked.

The dummy insulation layer may be formed to include an oxide, e.g., silicon oxide, the dummy gate electrode layer may be formed to include, e.g., polysilicon, and the hard mask layer may be formed to include a nitride, e.g., silicon nitride. The dummy insulation layer may be formed by a chemical vapor deposition (CVD) process, an atomic layer deposition (ALD) process, etc. In some embodiments, the dummy insulation layer may be formed by a thermal oxidation process on an upper portion of the substrate 100. The dummy gate electrode layer and the hard mask layer may be also formed by a CVD process, an ALD process, etc.

In example embodiments, each of the dummy gate structures 112 may be formed to extend in the second direction on the preliminary active fins 104 and the isolation layer 102, and the plurality of dummy gate structures 112 may be formed to be spaced apart from each other by a given distance in the first direction.

A spacer layer may be formed on the dummy gate structures 112, the preliminary active fins 104 and the isolation layer 102. The spacer layer may be anisotropically etched to form the spacers 114 on sidewalls of each of the dummy gate structures 112.

The preliminary active fin 104 may be partially removed using the dummy gate structures 112 and the spacers 114 as an etch mask to form the recess 116. Thus, an active fin 105 may be formed to include a first pattern 105a extending in the first direction and a second pattern 105b protruding from a top surface of the first pattern 105a.

In example embodiments, the etching processes for forming the spacers 114 and the recess 116 may be performed in-situ.

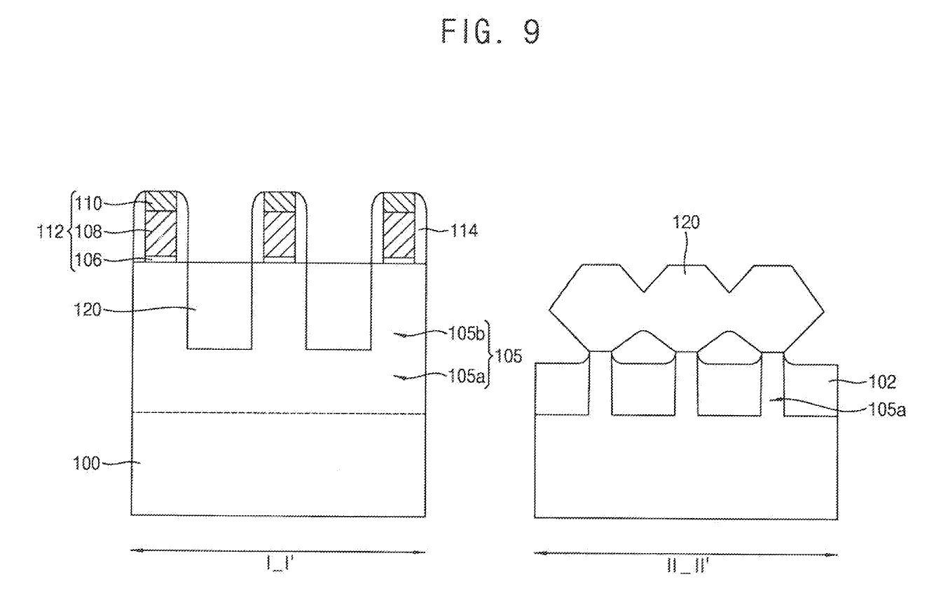

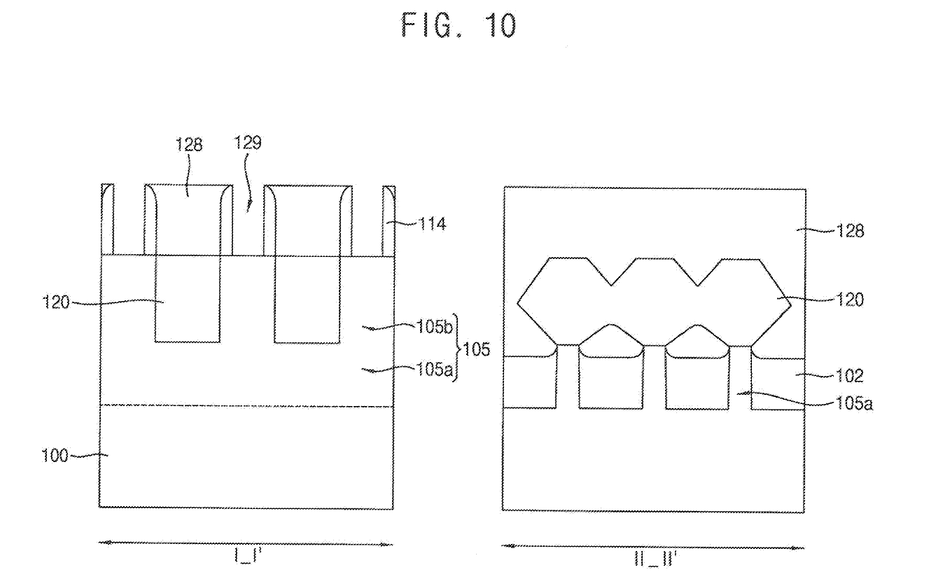

Referring to FIG. 9, an epitaxial pattern may be formed to be within and, in some embodiments, substantially fill the recess 116. In example embodiments, a plurality of epitaxial patterns may be formed in the second direction. Sidewalls of the epitaxial patterns in the second direction may contact each other to be merged into a single layer, which may be referred to as an epitaxial structure 120.

In example embodiments, a selective epitaxial growth (SEG) process may be performed using a surface portion of the active fin 105 exposed by the recess 116 as a seed to form the epitaxial patterns. The epitaxial patterns may be grown not only in a vertical direction but also in a horizontal direction, and thus the epitaxial structure 120 may be formed. Each of the epitaxial patterns may be formed to have a cross-section taken along the second direction of which a shape may be a pentagon, hexagon, or rhombus, however the present inventive concepts are not limited thereto.

In example embodiments, when the SEG process is performed, impurities may be doped in-situ into the epitaxial structure 120. Thus, the epitaxial structure 120 including the epitaxial patterns may serve as a source/drain region of a FinFET.

In will be understood that while only one epitaxial structure 120 is illustrated in FIG. 9, a plurality of epitaxial structures 120 extending in the second direction may be formed arranged in the first direction. In example embodiments, each of the epitaxial structures 120 may be formed of silicon or silicon-germanium. In some embodiments, when a PMOS transistor is formed, the epitaxial structure 120 may be formed of silicon-germanium, and may be doped with p-type impurities. In some embodiments, when an NMOS transistor is formed, the epitaxial structure 120 may be formed of silicon, and may be doped with n-type impurities

In example embodiments, after performing the SEG process, impurities may be further implanted into the active fin 105, and the substrate 100 may be annealed.

Referring to FIG. 10, a first insulating interlayer 128 may be formed on the substrate 100 to cover the dummy gate structures 112, the spacers 114, the epitaxial structure 120 and the isolation layer 102. An upper portion of the first insulating interlayer 128 may be planarized until top surfaces of the dummy gate structures 112 may be exposed.

In example embodiments, the first insulating interlayer 128 may be formed to include, e.g., silicon oxide. In example embodiments, the planarization process may be performed by a chemical mechanical polishing (CMP) process and/or an etch back process.

The exposed dummy gate structures 112 may be removed to form openings 129 exposing surfaces of the active fin 105 and the isolation layer 102. In example embodiments, the exposed surface of the active fin 105 may be, e.g., thermally oxidized to form a thermal oxide layer (not shown).

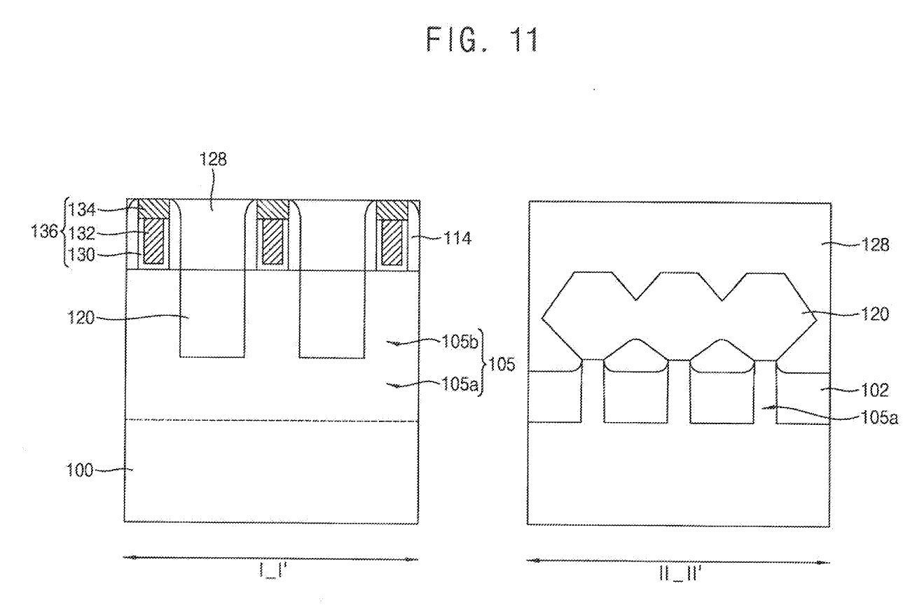

Referring to FIG. 11, a gate structure 136 may be formed in and, in some embodiments, substantially fill, each of the openings 129. The gate structure 136 may include a gate insulation pattern 130, a gate electrode 132, and a hard mask 134 sequentially stacked.

Particularly, a high-k dielectric layer may be formed on surfaces of the thermal oxide layer, the isolation layer 102 and the first insulating interlayer 128 and sidewalls of the openings 129, and a gate electrode layer may be formed on the high-k dielectric layer to fill remaining portions of the openings 129.

The high-k dielectric layer may be formed to include a metal oxide having a high dielectric constant, e.g., hafnium oxide, tantalum oxide, zirconium oxide, etc. The gate electrode layer may be formed to include a material having a low resistance, e.g., a metal such as aluminum, copper, tantalum, etc., or a metal nitride thereof by an ALD process, a physical vapor deposition (PVD) process, etc.

The gate electrode layer and the high-k dielectric layer may be planarized until the top surface of the first insulating interlayer 128 may be exposed, and may be partially etched to form the gate insulation pattern 130 on an inner surface of each of the openings 129, and the gate electrode 132 filling a lower portion of each of the openings 129 on the gate insulation pattern 130. In example embodiments, the planarization process may be performed by a CMP process and/or an etch back process. A hard mask layer may be formed on the gate electrode 132 and the gate insulation pattern 130 to be within and, in some embodiments, substantially fill a remaining portion of each of the openings 129. The hard mask layer may be planarized until the top surface of the first insulating interlayer 128 may be exposed to form the hard mask 134.

The gate insulation pattern 130, the gate electrode 132, and the hard mask 134 sequentially stacked may define the gate structure 136.

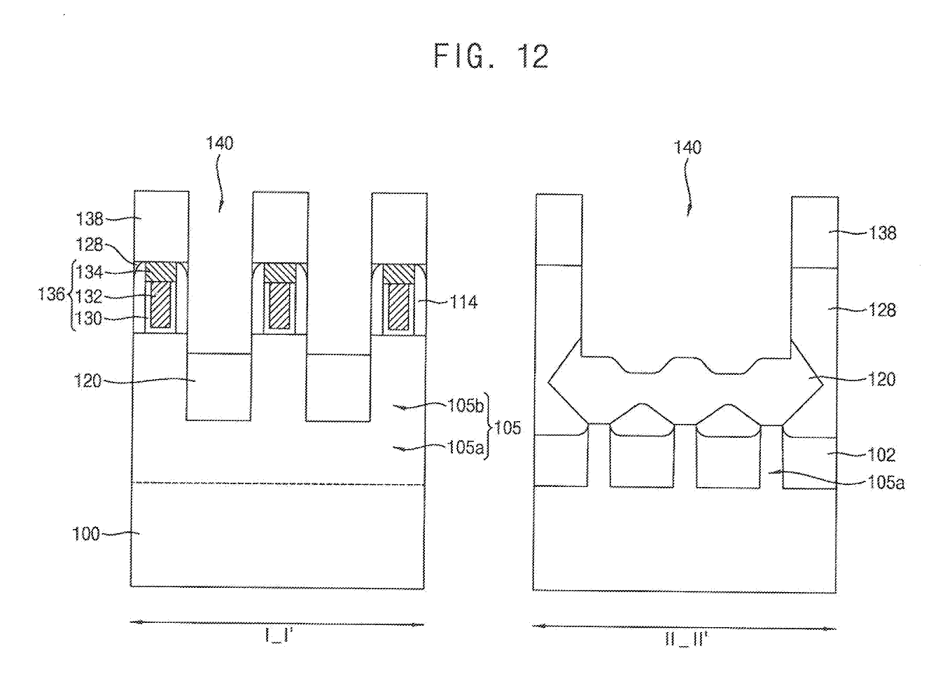

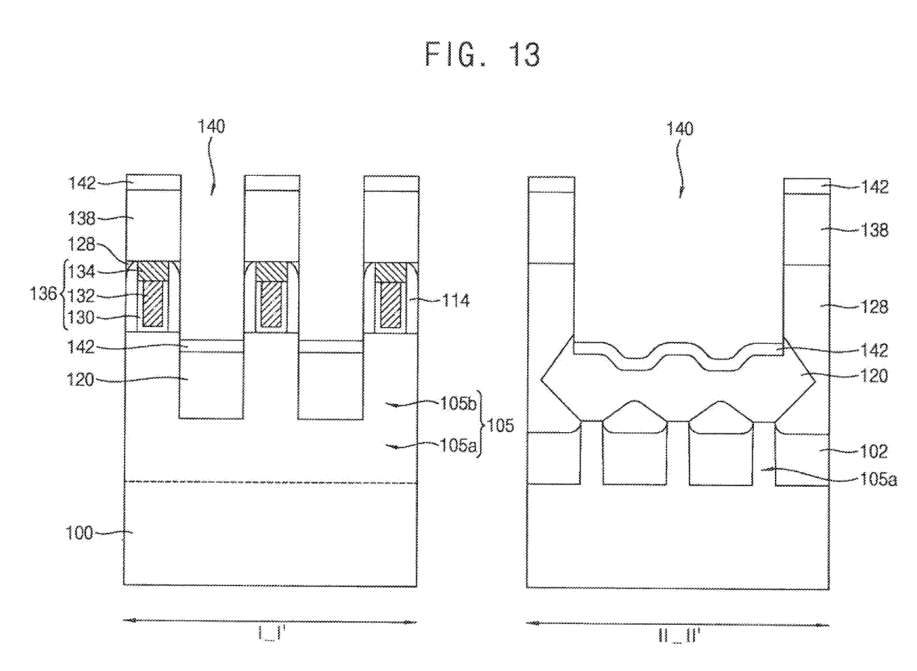

Referring to FIG. 12, a second insulating interlayer 138 may be formed on the first insulating interlayer 128. The first and second insulating interlayers 128 and 138 may be etched to form a contact hole 140 exposing an upper surface of the epitaxial structure 120.

In example embodiments, the second insulating interlayer 138 may be formed to include a material substantially the same as that of the first insulating interlayer 128.

In example embodiments, the first and second insulating interlayers 128 and 138 may be over-etched, so that an upper surface of the epitaxial structure 120 may be partially etched.

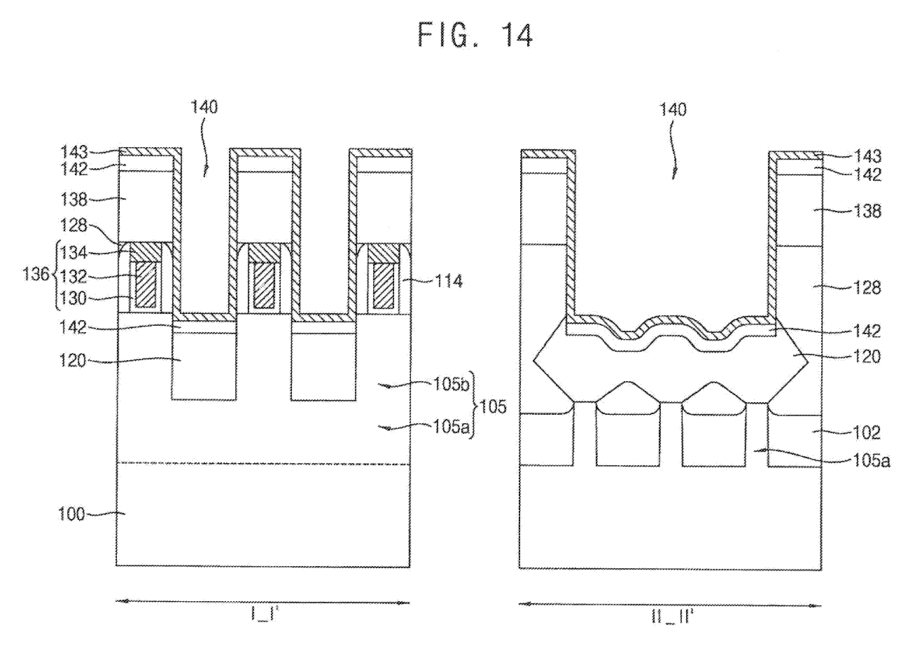

Referring to FIG. 13, a preliminary ohmic layer 142 including a metal may be formed on the contact hole 140 and the second insulating interlayer 138. In example embodiments, the preliminary ohmic layer 142 may be formed by a PVD process. In this case, the preliminary ohmic layer 142 may be deposited to have poor step coverage characteristic, so that the preliminary ohmic layer 142 may be selectively formed on an upper surface of the second insulating interlayer and the bottom of the contact hole 140. However, the preliminary ohmic layer 142 may not be formed on a sidewall of the contact hole 140. As the preliminary ohmic layer may be deposited by the PVD process, the preliminary ohmic layer 142 may be discontinuously formed and have a high purity.

In example embodiments, the preliminary ohmic layer 142 may be formed of, e.g., titanium, tantalum, etc. The preliminary ohmic layer 142 may be formed to have a first thickness. In example embodiments, the first thickness may be about 5 nm to about 20 nm.

Referring to FIG. 14, a preliminary first barrier layer 143 may be conformally formed on the surface of the preliminary ohmic layer 142 and the sidewall of the contact hole 140.

In example embodiments, the preliminary first barrier layer 143 may be formed by a CVD process or an ALD process. The CVD process may include, e.g., a metal organic CVD process. The ALD process may include, e.g., a metal organic ALD process.

In example embodiments, the preliminary first barrier layer 143 may include a metal nitride. In example embodiments, the preliminary first barrier layer 143 may include a metal substantially the same as a metal included in the preliminary ohmic layer 142. For example, the preliminary first barrier layer 143 may include titanium nitride and/or tantalum nitride.

The preliminary first barrier layer 143 may be formed to have a second thickness such that nitrogen ions may permeate into an underlying layer. The second thickness may be less than the first thickness. In example embodiments, the second thickness may be about 1 nm to about 10 nm.

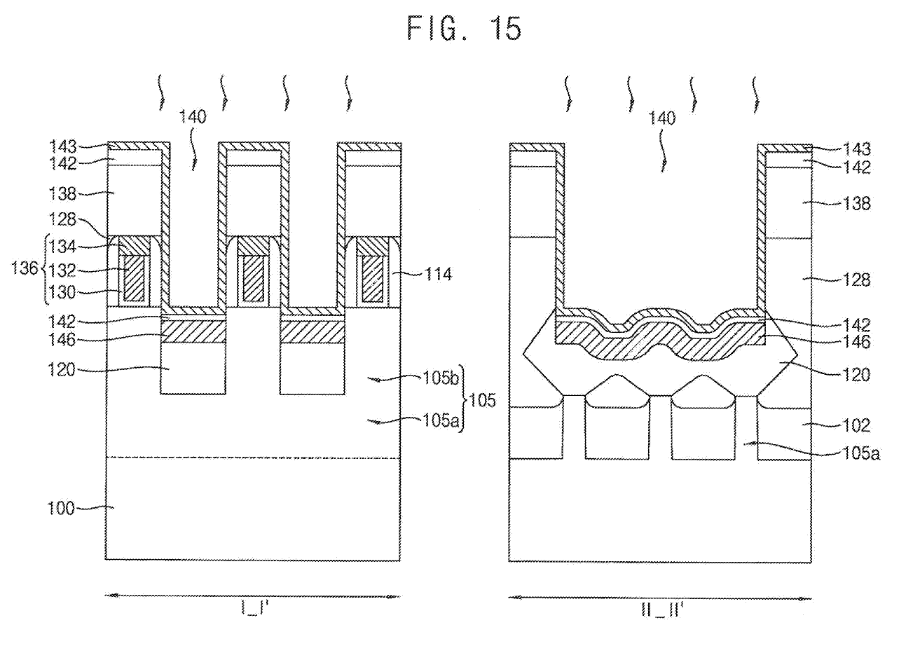

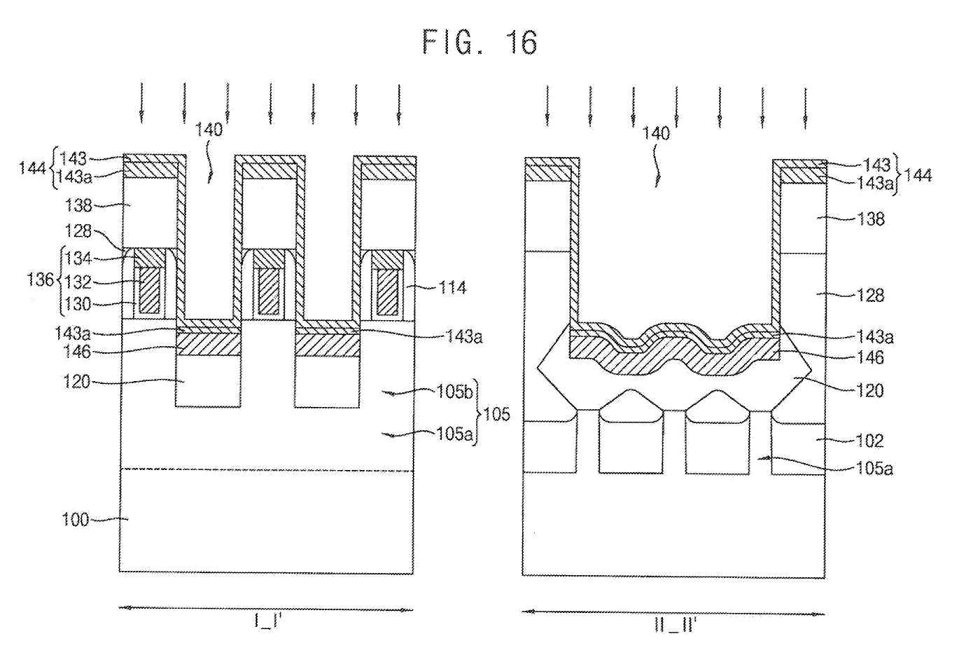

Referring to FIG. 15, the preliminary ohmic layer 142 and the preliminary first barrier layer 143 may be annealed, so that a portion of the preliminary ohmic layer 142 may be silicidated. That is, the preliminary ohmic layer 142 on the bottom of the contact hole 140 may be reacted with the epitaxial structure 120 to form a metal silicide pattern 146 on the epitaxial structure 120.

In example embodiments, the annealing process may be performed at a temperature of about 600° C. to about 1000° C. In example embodiments, the annealing process may be performed under an atmospheric pressure, and may use an ambient gas, such as nitrogen gas, NH₃ gas, etc. In example embodiments, the annealing process may include a laser annealing process.

In example embodiments, a lower portion of the preliminary ohmic layer 142 directly on the epitaxial structure 120 may be transformed into the metal silicide pattern 146, and an upper portion of the preliminary ohmic layer 142 may remain on the metal silicide pattern 146. In some embodiments, all of the preliminary ohmic layer 142 on the epitaxial structure 120 may be transformed into the metal silicide pattern 146, so that the preliminary ohmic layer 142 may not remain on the metal silicide pattern 146.

The preliminary first barrier layer 143 may be formed to have a thin thickness, so that most of the preliminary ohmic layer 142 may be transformed into the metal silicide pattern 146 by the annealing process.

Thus, the metal silicide pattern 146 may include a metal substantially the same as a metal included in the preliminary ohmic layer 142. In example embodiments, the metal silicide pattern 146 may be formed of, e.g., titanium silicide, tantalum silicide, etc. The metal silicide pattern 146 may serve as an ohmic pattern of a contact structure.

In example embodiments, an upper surface of the metal silicide pattern 146 may be lower than a top surface of the second pattern 105b of the active fin 105. In example embodiments, a bottom of the metal silicide pattern 146 may contact an upper portion of the epitaxial structure 120 having a high impurity concentration. Thus, a contact resistance between the metal silicide pattern 146 and the epitaxial structure 120 may decrease.

Referring to FIG. 16, a nitridation treatment may be performed on the metal silicide pattern 146, the preliminary ohmic layer 142, and the preliminary first barrier layer 143. Thus, the preliminary ohmic layer 142 may be transformed into the metal nitride layer 143a by the nitridation treatment.

The preliminary first barrier layer 143 may be formed to have a thin thickness so that nitrogen ions may permeate into an underlying layer. Thus, the remaining preliminary ohmic layer 142 on the metal silicide pattern 146 may be transformed into a metal nitride layer 143a by the nitridation treatment, and thus that the preliminary ohmic layer 142 including a metal may be removed. The metal nitride layer 143a may include a material substantially the same as the material of the preliminary first barrier layer 143, and thus the metal nitride layer 143a and the preliminary first barrier layer 143 may be merged into a single layer, which may be referred to as a first barrier layer 144.

The first barrier layer 144 including metal nitride may directly contact the metal silicide pattern 146. That is, an interface metal layer, such as a titanium layer or a tantalum layer may not be formed between the first barrier layer 144 and the metal silicide pattern 146.

In example embodiments, the nitridation treatment may include, e.g., a plasma nitridation process, a nitrogen ion implantation process, etc.

When the annealing process and the nitridation treatment are performed, defects may be generated in the preliminary first barrier layer 143. Thus, the first barrier layer 144 may have more defects than the preliminary barrier layer 143 before the annealing process and the nitridation treatment, and the first barrier layer 144 may have a size of a grain boundary greater than a size of a grain boundary of the preliminary barrier layer 143 before the annealing process and the nitridation treatment.

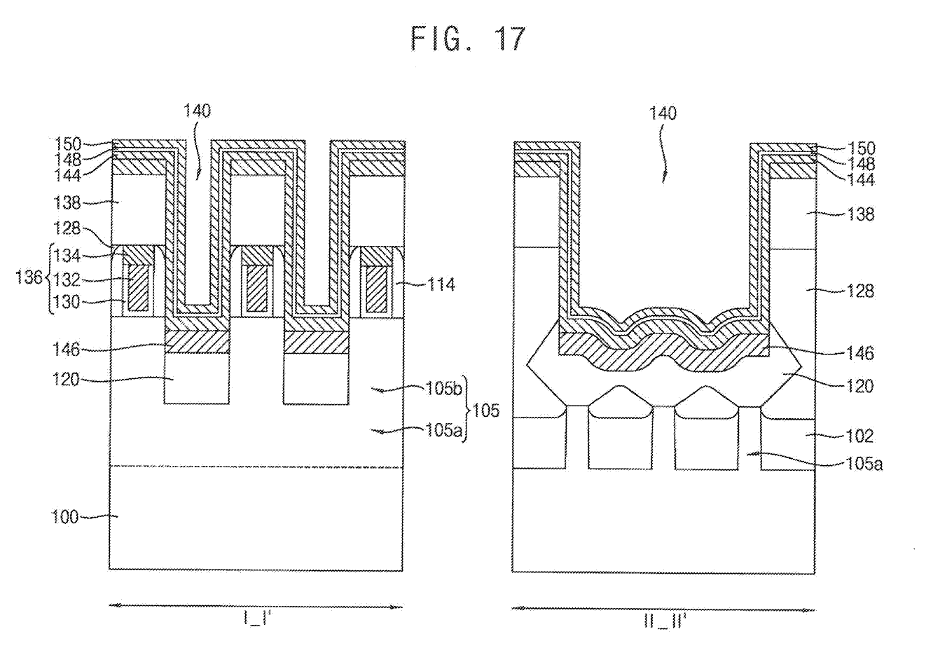

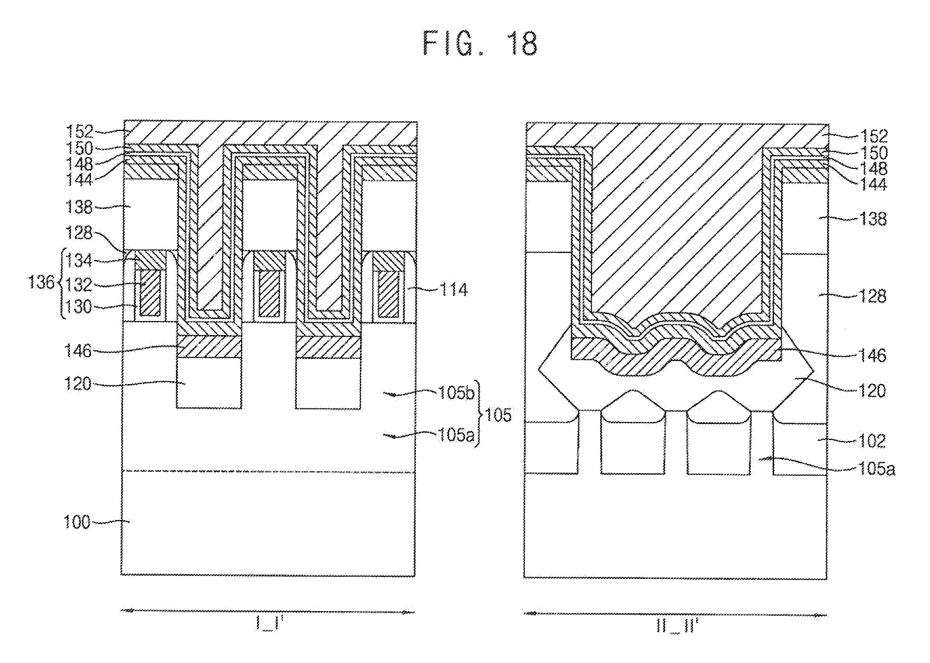

Referring to FIG. 17, a second barrier layer 150 may be formed on the first barrier layer 144.

In example embodiments, the second barrier layer 150 may be formed by a CVD process or an ALD process. The CVD process may include, e.g., a metal organic CVD process. The ALD process may include, e.g., a metal organic ALD process.

In example embodiments, the second barrier layer 150 may include a metal nitride substantially the same as the metal nitride of the first barrier layer 144. In some embodiments, the second barrier layer 150 may include a metal nitride different from the metal nitride of the first barrier layer 144. In some embodiments, when the second barrier layer 150 includes titanium nitride, the second barrier layer 150 may be formed by the CVD process or the ALD process using a titanium source gas, e.g., TiClₓ.

In example embodiments, when the second barrier layer 150 is formed, a portion of a surface of the first barrier layer 144 may be oxidized. In this case, a metal oxynitride layer 148 having a thin thickness may be formed on the first barrier layer 144. Thus, the first barrier layer 144, the metal oxynitride layer 148 and the second barrier layer 150 may be formed on the metal silicide pattern 146. Thus, after subsequent processes are performed, the semiconductor device including the contact structure shown in FIGS. 1 and 3 may be manufactured.

In some embodiments, when the second barrier layer 150 is formed, the surface of the first barrier layer 144 may not be oxidized. In such embodiments, the second barrier layer 150 may directly contact the first barrier layer 144, and thus a metal oxynitride layer may not be formed on the first barrier layer 144. Thus, after subsequent processes are performed, the semiconductor device including the contact structure shown in FIG. 5 may be manufactured.

In some embodiments, when the second barrier layer 150 is formed, most of the first barrier layer 144 may be oxidized to be transformed into a metal oxynitride layer. In this case, the first barrier layer 144 may include metal oxynitride. Thus, after subsequent processes are performed, the semiconductor device including the contact structure shown in FIG. 6 may be manufactured.

In example embodiments, the annealing process and the nitridation treatment may not be performed on the second barrier layer 150, so that a size of the grain boundary of the second barrier layer 150 may be less than a size of the grain boundary of the first barrier layer 144. Thus, grain boundaries may be mismatched at an interface between the first and second barrier layers 144 and 150. Also, the number and/or size of the defects included in the second barrier layer 150 may be less than the number and/or size of the defects included in the first barrier layer 144.

In example embodiments, a structure including the first barrier layer 144, the metal oxynitride layer 148, and the second barrier layer 150 sequentially stacked may serve as a diffusion barrier layer against a metal. The diffusion barrier layer may be formed to have a thickness of about 2 nm to 20 nm. Thus, a thickness of the second barrier layer 150 may be controlled according to a thickness of the first barrier layer 144.

Referring to FIG. 18, a metal layer 152 may be formed on the second barrier layer 150 in and, in some embodiments, sufficiently fill, remaining portions of the contact holes 140.

The metal layer 152 may be formed by a CVD process or an ALD process. The metal layer 152 may be formed of, e.g., tungsten, copper, aluminum, etc.

In some embodiments, when the metal layer 152 includes tungsten, the metal layer 152 may be formed using a tungsten source gas, e.g., WF₆. In example embodiments, the tungsten layer may be formed by an ALD process in which the tungsten source gas, e.g., WF₆ and a reducing gas, e.g., H₂ are alternately provided.

When the metal layer 152 is formed, a metal such as titanium may not be formed under the metal layer 152. If a metal material layer is formed under the metal layer, the metal material layer may be reacted with gases, e.g., fluorine gas in the WF₆ for forming the metal layer. Thus, the metal material layer may be removed by the gases, and a void may be formed from the metal material layer. However, in example embodiments of the inventive concepts, the metal material layer may not be formed under the metal layer 152, so that the void may not be formed.

When the metal layer 152 is formed, metal diffusion may be decreased by the first barrier layer 144, the metal oxynitride layer 148 and the second barrier layer 150. Thus, a surface of the metal layer 152 may have a good morphology characteristic.

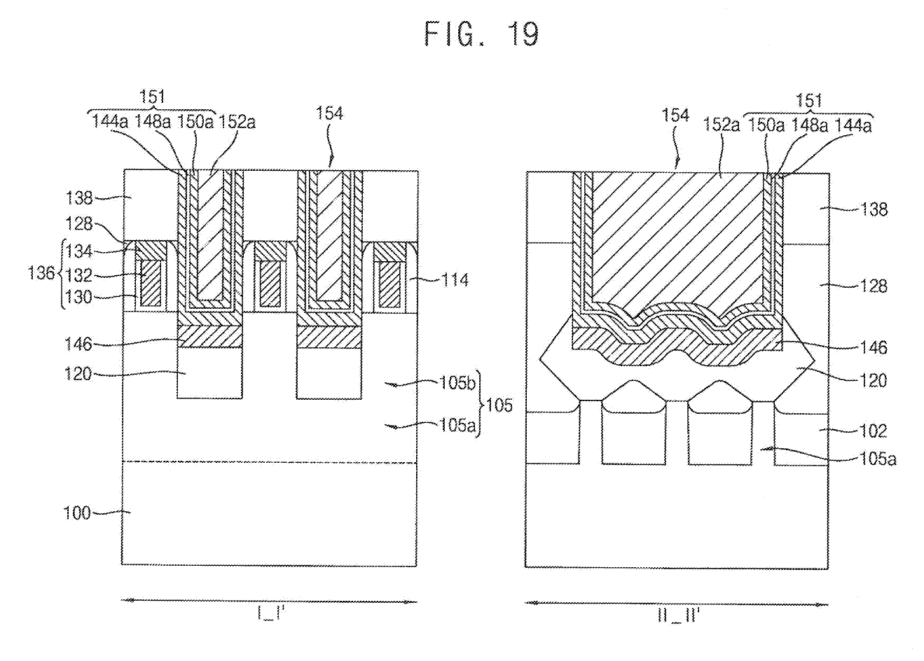

Referring to FIG. 19, the second barrier layer 150, the metal oxynitride layer 148, the first barrier layer 144 and the metal layer 152 may be planarized until an upper surface of the second insulating interlayer 138 may be exposed to form a contact structure 154 within and, in some embodiments, substantially filling the contact hole 140.

In example embodiments, the planarization process may be performed by a CMP process and/or an etch back process. In some example embodiments, the preliminary ohmic layer 142 may remain on the second insulating interlayer 138. In this case, the preliminary ohmic layer 142 may be completely removed by the planarization process.

The contact structure 154 may include the metal silicide pattern 146, the first barrier pattern 144a, the metal oxynitride pattern 148a, the second barrier pattern 150a and the metal pattern 152a. The first and second barrier patterns 144a and 150a may include a metal nitride. The metal silicide pattern 146 may directly contact the first barrier pattern 144a. That is, an interface metal layer may not be formed between the metal silicide pattern 146 and the first barrier pattern 144a. A structure including the first barrier pattern 144a, the metal oxynitride pattern 148a, and the second barrier pattern 150a sequentially stacked may serve as a barrier pattern structure 151.

A conductive pattern (not shown) may be formed on the contact structure 154, so that the conductive pattern and the contact structure 154 may be electrically connected to each other. The conductive pattern may include, e.g., a pad electrode, a conductive line, etc.

In this example embodiment, the contact structure 154 may contact the source/drain regions in the finFET, however, the inventive concepts may not be limited thereto. For example, the contact structure 154 may be used in a contact plug directly contacting a substrate or a silicon pattern in various types of semiconductor devices. In some example embodiments, the transistor may be, e.g., a planar-type channel array transistor (PCAT), a buried channel array transistor (BCAT), a multi-channel array transistor, etc.

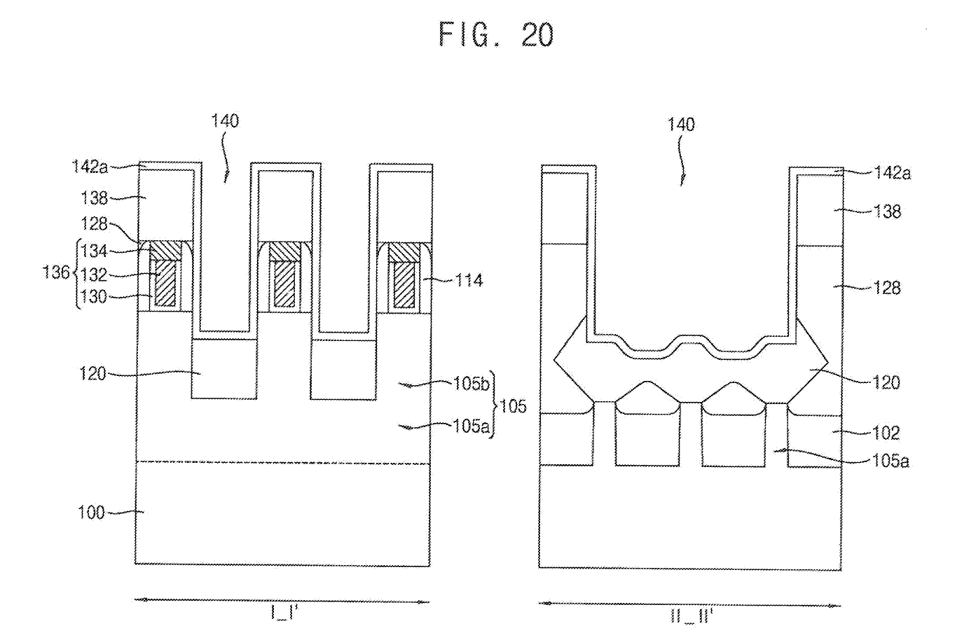

FIGS. 20 to 23 are cross-sectional views illustrating stages of a method of manufacturing the semiconductor device in accordance with example embodiments of the inventive concepts.

Particularly, each of FIGS. 20 to 23 includes cross-sectional views taken along lines I-I′ and II-II′ of FIG. 2, respectively.

Referring to FIG. 20, first, processes substantially the same as or similar to those illustrated with reference to FIGS. 7 to 12 may be performed. Then, the preliminary ohmic layer 142a may be formed on the contact hole 140 and the first and second insulating interlayers 128 and 138. In example embodiments, the preliminary ohmic layer 142a may be formed by a CVD or an ALD process. In this case, the preliminary ohmic layer 142a may be formed on a sidewall and a bottom of the contact hole 140 and an upper surface of the second insulating interlayer 138.

In example embodiments, the preliminary ohmic layer 142a may be formed of, e.g., titanium, tantalum, etc. The preliminary ohmic layer 142a may be formed to have a first thickness. In example embodiments, the first thickness may be about 5 nm to about 20 nm.

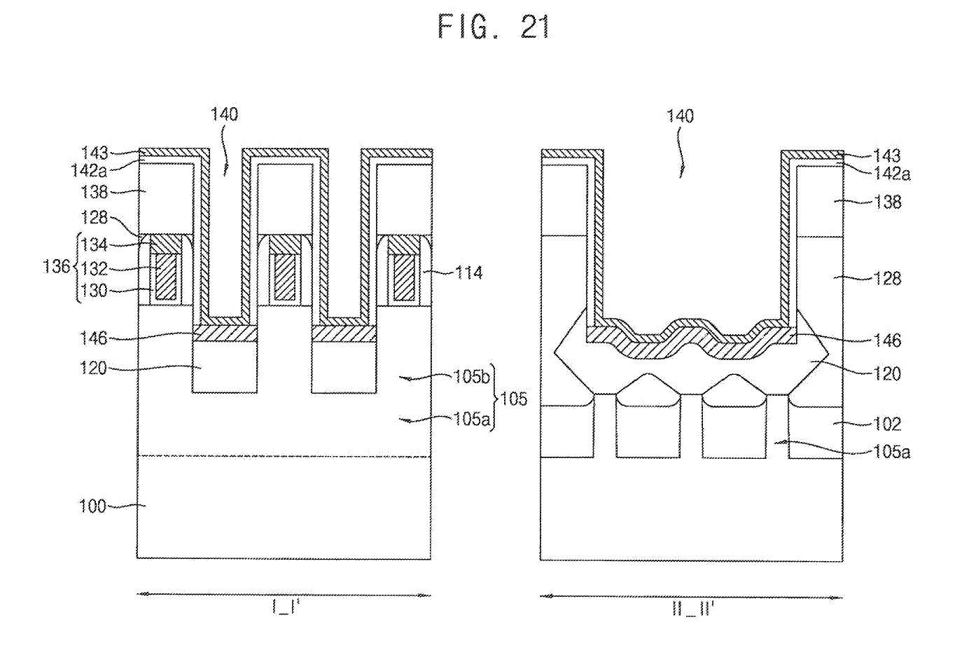

Referring to FIG. 21, the preliminary first barrier layer 143 may be conformally formed on the surface of the preliminary ohmic layer 142a.

The preliminary ohmic layer 142a and the preliminary first barrier layer 143 may be annealed, so that a portion of the preliminary ohmic layer 142a may be silicidated. That is, the preliminary ohmic layer 142a on the bottom of the contact hole 140 may be reacted with the epitaxial structure 120 to form the metal silicide pattern 146 on the epitaxial structure 120.

In example embodiments, substantially all of the preliminary ohmic layer 142a on the bottom of the contact hole 140 may be transformed into the metal silicide pattern 146. In some embodiments, a lower portion of the preliminary ohmic layer 142a directly on the epitaxial structure 120 may be transformed into the metal silicide pattern 146, and an upper portion of the preliminary ohmic layer 142a may remain on the metal silicide pattern 146.

The above processes may be substantially the same as or similar to those illustrated with reference to FIGS. 14 to 15.

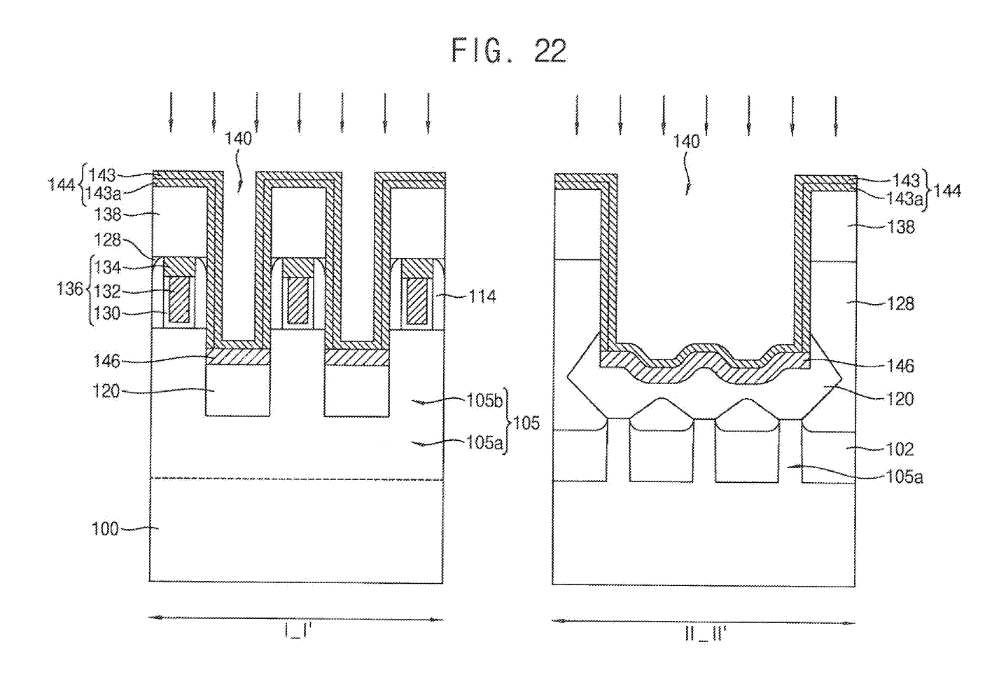

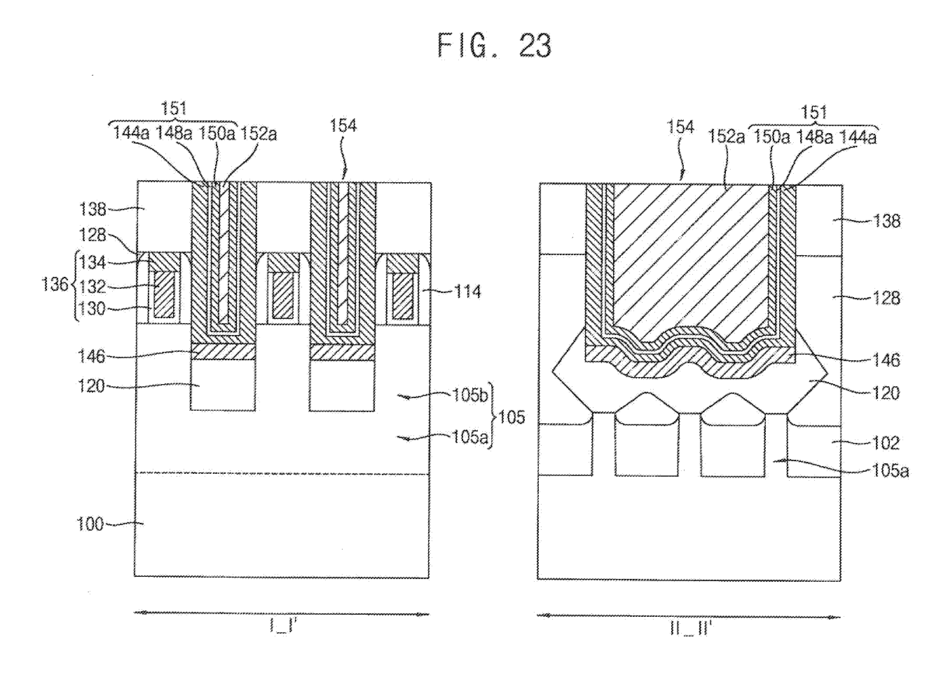

Referring to FIG. 22, a nitridation treatment may be performed on the metal silicide pattern 146, the preliminary ohmic layer 142a, and the preliminary first barrier layer 143. Thus, the preliminary ohmic layer 142a may be transformed into the metal nitride 143a by the nitridation treatment.

That is, the preliminary ohmic layer 142a on the sidewall, the bottom of the contact hole 140 (if present), and the upper surface of the second insulating interlayer 138 may be transformed into the metal nitride 143a including substantially the same material as that of the preliminary first barrier layer 143. Thus, the metal nitride 143a and the preliminary first barrier layer 143 may be merged into a single layer, which may be referred to as the first barrier layer 144.

The first barrier layer 144 including metal nitride may be directly contact the metal silicide pattern 146. That is, an interface metal layer, such as a titanium layer or a tantalum layer may not be formed between the first barrier layer 144 and the metal silicide pattern 146.

In example embodiments, the nitridation treatment may include, e.g., a plasma nitridation process, a nitrogen ion implantation process, etc.

Then, processes substantially the same as or similar to those illustrated with reference to FIGS. 17 to 19 may be performed. Thus, a semiconductor shown in FIG. 23 may be manufactured.

The semiconductor device may be substantially the same as the semiconductor device shown in FIGS. 1 to 4, except for a thickness of the first barrier pattern 144a on the sidewall of the contact hole 140. Particularly, the thickness of the first barrier pattern 144a on the sidewall of the contact hole 140 may be greater than that of the first barrier pattern 144a in the semiconductor device shown in FIGS. 1 to 4. In some embodiments, the thickness of the first barrier pattern 144a on the sidewall of the contact hole 140 may be greater than the thickness of the first barrier pattern 144a on the bottom of the contact hole 140.

The above semiconductor device may be applied to various types of systems, e.g., computing systems.

It will be understood that although the terms “first”, “second”, etc. are used herein to describe members, regions, layers, portions, sections, components, and/or elements in example embodiments of the inventive concepts, the members, regions, layers, portions, sections, components, and/or elements should not be limited by these terms. These terms are only used to distinguish one member, region, portion, section, component, or element from another member, region, portion, section, component, or element. Thus, a first member, region, portion, section, component, or element described below may also be referred to as a second member, region, portion, section, component, or element without departing from the scope of the inventive concepts. For example, a first element may also be referred to as a second element, and similarly, a second element may also be referred to as a first element, without departing from the scope of the inventive concepts.

Spatially relative terms, such as “beneath,” “below,” “lower,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by those of ordinary skill in the art to which the inventive concepts pertain. It will also be understood that terms, such as those defined in commonly used dictionaries, should be interpreted as having a meaning that is consistent with their meaning in the context of this specification and the relevant art and will not be interpreted in an idealized or overly formal sense unless expressly so defined herein.

When a certain example embodiment may be implemented differently, a specific process order may be performed differently from the described order. For example, two consecutively described processes may be performed substantially at the same time or performed in an order opposite to the described order.

In the accompanying drawings, variations from the illustrated shapes as a result, for example, of manufacturing techniques and/or tolerances, are to be expected. Thus, the example embodiments of the inventive concepts should not be construed as being limited to the particular shapes of regions illustrated herein but may be construed to include deviations in shapes that result, for example, from a manufacturing process. For example, an etched region illustrated as a rectangular shape may be a rounded or certain curvature shape. Thus, the regions illustrated in the figures are schematic in nature, and the shapes of the regions illustrated in the figures are intended to illustrate particular shapes of regions of devices and not intended to limit the scope of the present inventive concepts. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a structure comprising silicon on a substrate;
an insulating interlayer on the structure, the insulating interlayer including a contact hole exposing a surface of the structure;
a metal silicide pattern within a lower portion of the contact hole, the metal silicide pattern directly contacting the exposed surface of the structure;
a first barrier pattern directly contacting an upper surface of the metal silicide pattern and a sidewall of the contact hole, the first barrier pattern including a metal nitride;
a second barrier pattern on the first barrier pattern, the second barrier pattern including a metal nitride; and
a metal pattern on the second barrier pattern, the metal pattern within the contact hole.

2. The device of claim 1, wherein a metal included in the first barrier pattern is substantially the same as a metal included in the metal silicide pattern.

3. The device of claim 1, wherein the first barrier pattern includes titanium nitride or tantalum nitride.

4. The device of claim 1, further comprising a metal oxynitride layer between the first and second barrier patterns.

5. The device of claim 4, wherein the metal oxynitride layer is an oxide of the metal nitride included in the first barrier pattern.

6. The device of claim 1, wherein the first and second barrier patterns include a material substantially the same as each other.

7. The device of claim 1, wherein a size of a grain boundary of the first barrier pattern is different from a size of a grain boundary of the second barrier pattern.

8. The device of claim 7, wherein the size of the grain boundary of the first barrier pattern is less than the size of the grain boundary of the second barrier pattern.

9. The device of claim 1, further comprising:
an active fin on the substrate, the active fin extending in a first direction and including a plurality of protruding portions and a plurality of recesses between neighboring ones of the protruding portions; and
a gate structure between two adjacent recesses of the plurality of recesses, the gate structure extending in a second direction crossing the first direction,
wherein the structure is in one of the two adjacent recesses.

10. A semiconductor device comprising:
a substrate including an active fin, the active fin including a plurality of protruding portions and a plurality of recesses between neighboring ones of the protruding portions;
a gate structure extending in a second direction crossing the first direction, the gate structure on one of the protruding portions of the active fin;
an epitaxial structure comprising silicon within a recess of the plurality of recesses;
an insulating interlayer on the epitaxial structure, the insulating interlayer including a contact hole exposing a surface of the epitaxial structure;
a metal silicide pattern within a lower portion of the contact hole, the metal silicide pattern directly contacting the exposed surface of the structure;
a first barrier pattern directly contacting an upper surface of the metal silicide pattern and a sidewall of the contact hole, the first barrier pattern including a metal nitride;
a second barrier pattern on the first barrier pattern, the second barrier pattern including a metal nitride; and
a metal pattern on the second barrier pattern, the metal pattern in the contact hole.

11. The device of claim 10, wherein a metal included in the first barrier pattern is substantially the same as a metal included in the metal silicide pattern.

12. The device of claim 10, wherein the first barrier pattern includes titanium nitride or tantalum nitride.

13. The device of claim 10, further comprising a metal oxynitride layer between the first and second barrier patterns.

14. The device of claim 10, wherein the first barrier pattern has a thickness about 1 nm to about 10 nm.

15. The device of claim 10, wherein a size of a grain boundary of the first barrier pattern is different from a size of a grain boundary of the second barrier pattern.

16. A semiconductor device comprising:
a substrate;
an insulating interlayer on the substrate;
an epitaxial structure between the substrate and the insulating interlayer;
a contact hole in the insulating interlayer having a bottom portion of the contact hole above the epitaxial structure;
a metal silicide pattern in the bottom portion of the contact hole and above the epitaxial structure; and
a barrier pattern structure directly on the metal silicide pattern, the barrier pattern structure comprising:
a first barrier pattern directly contacting the metal silicide pattern; and
a second barrier pattern on the first barrier pattern,
wherein the first barrier pattern comprises a metal nitride or a metal oxynitride.

17. The semiconductor device of claim 16, further comprising:
an active fin on the substrate, wherein the active fin comprises a recess portion and a protruding portion, wherein the epitaxial structure is in the recess portion of the active fin, and wherein an upper surface of the metal silicide pattern is lower than a top surface of the protruding portion of the active fin.

18. The semiconductor device of claim 16, wherein the barrier pattern structure further comprises a metal oxynitride pattern between the first barrier pattern and the second barrier pattern.

19. The semiconductor device of claim 16, wherein a size of a grain boundary of the second barrier pattern is less than a size of a grain boundary of the first barrier pattern.

20. The semiconductor device of claim 16, wherein the first barrier pattern and the second barrier pattern are on a sidewall of the contact hole, and wherein a first thickness of the first barrier pattern on the sidewall of the contact hole is greater than a second thickness of a portion of the first barrier pattern that directly contacts the metal silicide pattern.
